(19) United States
(12) Patent Application Publication
(10) Pub. No.: US 2026/0206170 A1
(43) Pub. Date: Jul. 16, 2026

(54) CHASSIS AND SERVER

(71) Applicant: Fulian Precision Electronics (Tianjin) Co., LTD., Tianjin (CN)

(72) Inventors: WEI-TING LIAO, New Taipei (TW); HSIANG-YU LIEN, New Taipei (TW)

(21) Appl. No.: 19/227,744

(22) Filed: Jun. 4, 2025

(30) Foreign Application Priority Data
Jan. 14, 2025 (CN) 202510057143.4

(51) Int. Cl. H05K 7/14

(52) U.S. Cl. CPC H05K 7/1489

(57) ABSTRACT

A chassis and server are provided. The chassis includes a base and a pulling component. The base contains a fixed-position connector for connecting a card. The pulling component includes a support, a handle, and two arms. The support is fixed within the base. The handle translates between a pull-out position and an initial position relative to the support. Each side of the handle has an arm, with one end rotatably connected to the support and the other movably and rotatably connected to the handle. Each arm has an unlock pin. To remove the card, pulling the handle from the initial position to the pull-out position moves the unlock pin with the arm to push the card, extracting it from the connector, saving effort. To install the card, the handle remains in the initial position, where the unlock pin does not interfere with the card, allowing connection to the connector.

### FIELD

The disclosure herein generally relates to information computing systems, and more particularly relates to a chassis and a server.

### BACKGROUND

Servers are usually equipped with a card, such as an expansion card, and the card sometimes needs to be removed from the server for maintenance or replacement. However, due to the compact structure of the server, removing the card from the server often requires significant force, resulting in strenuous operations.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a chassis in a server in an embodiment of the present application, showing a card ready to be connected to the connector.

FIG. 2 is an isometric view of the server and the chassis shown in FIG. 1, showing the card is connected to the connector.

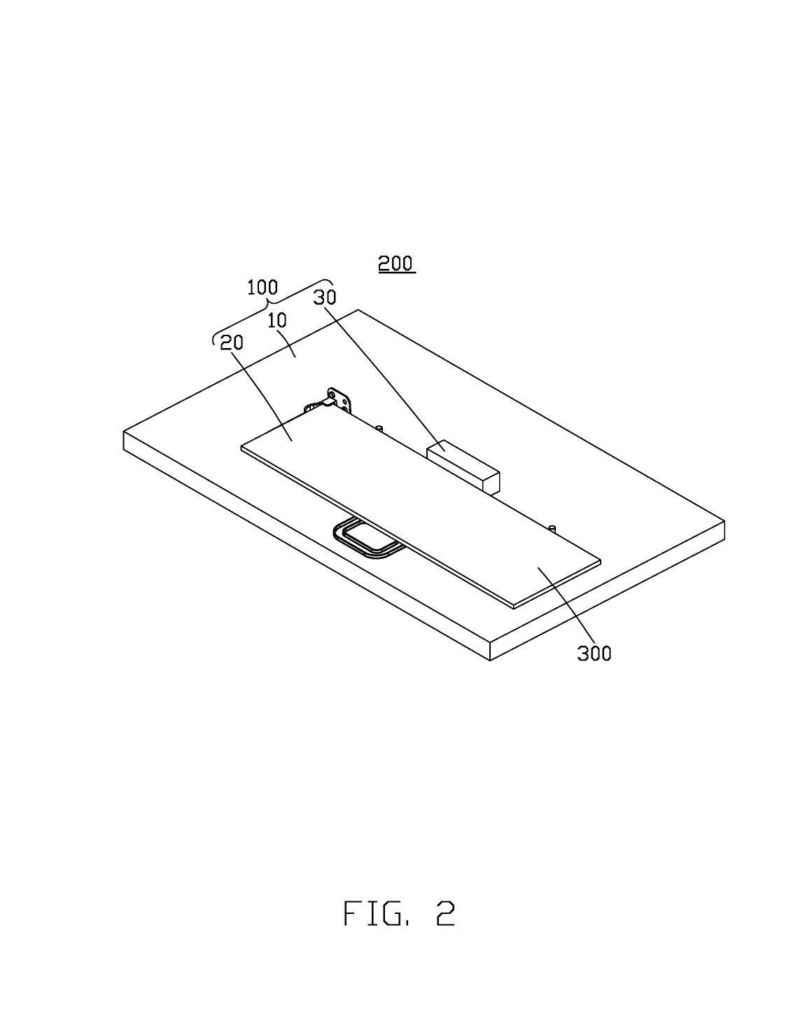

FIG. 3 is an isometric view of a pulling component shown in FIG. 1, showing the handle is in an initial position.

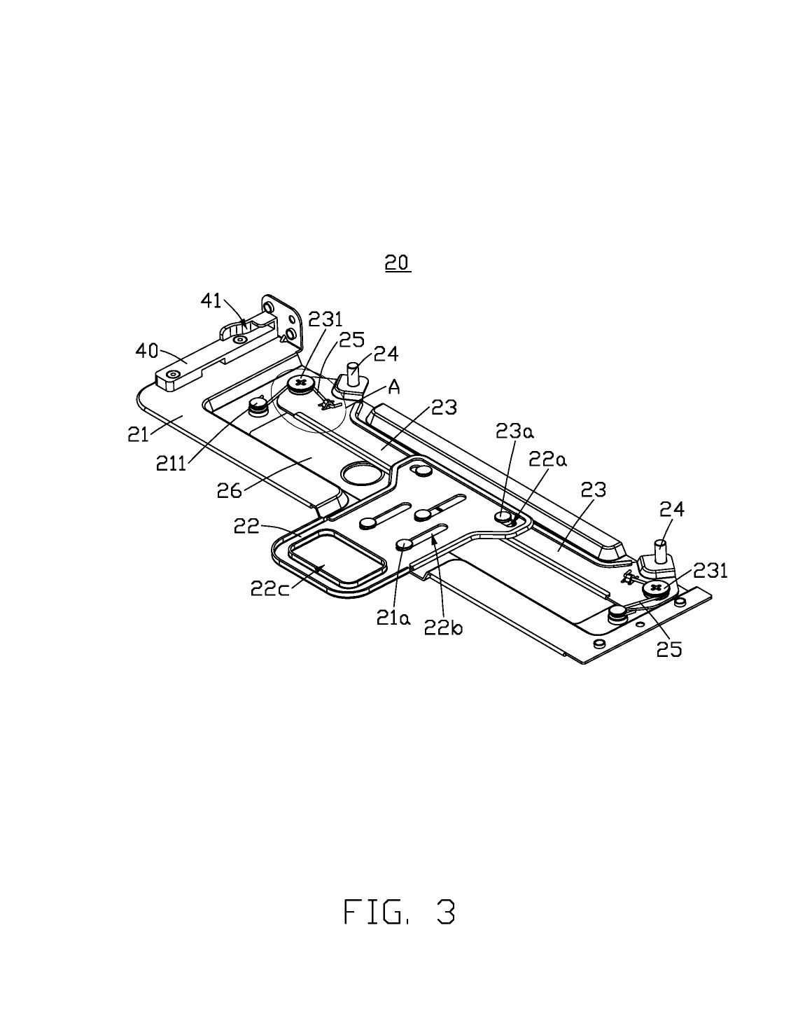

FIG. 4 is an isometric view of the pulling component shown in FIG. 3, showing the handle is in a pull-out position.

FIG. 5 is an exploded view of the pulling component shown in FIG. 3.

FIG. 6 is an enlarged view of area A shown in FIG. 3.

FIG. 7 is a cross-sectional view of an unlock pin shown in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

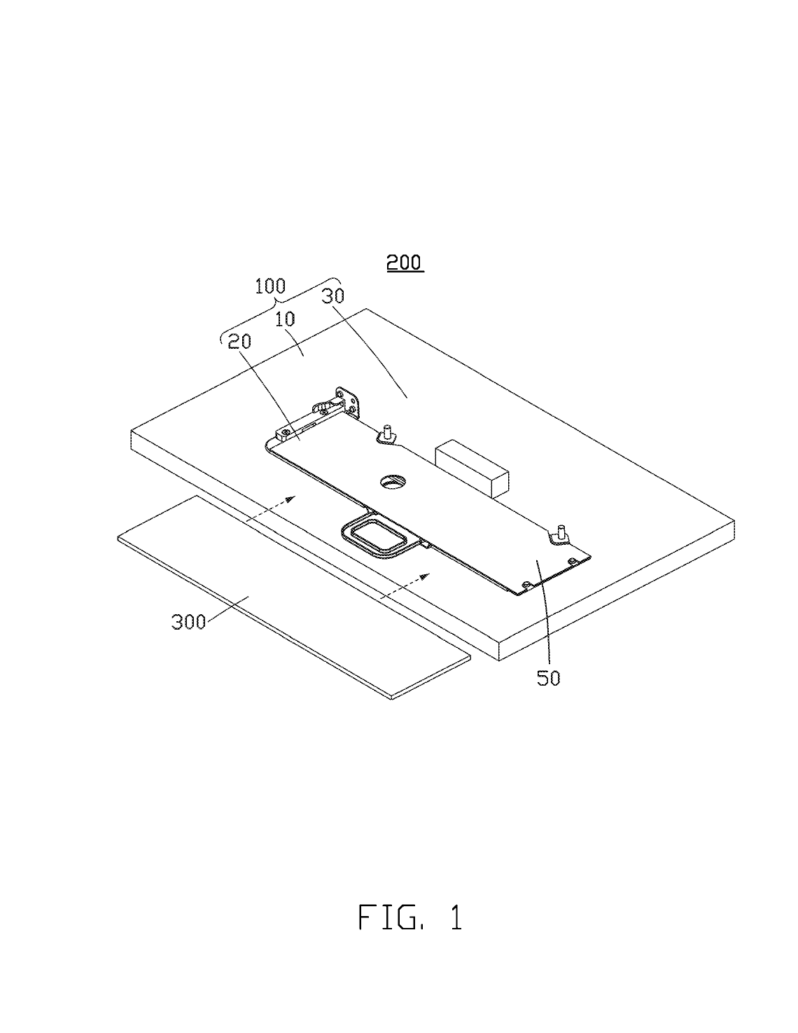

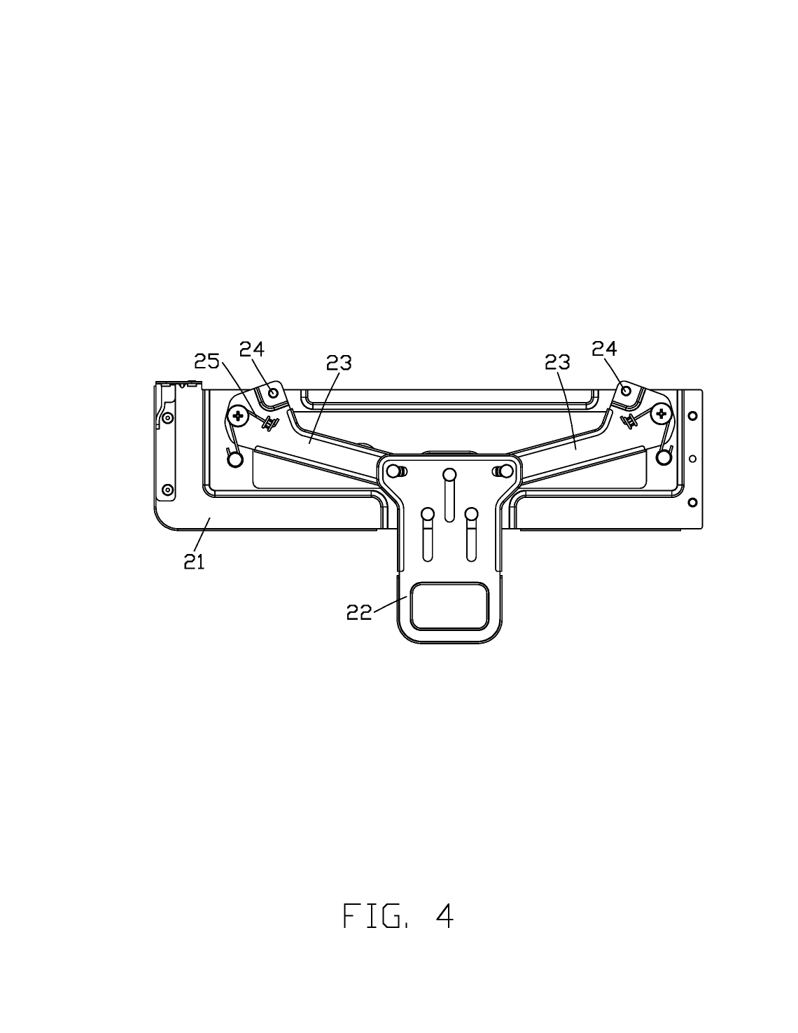

As shown in FIG. 1 and FIG. 4, an embodiment of the present application provides a server 200, which includes a chassis 100, a connector 30, and a card 300. The chassis 100 includes a base 10 and a pulling component 20. The connector 30 is fixed on the base 10. The connector 30 is used to connect the card 300, enabling electrical connection between the card 300 and the motherboard of the chassis 100. The pulling component 20 is located within the base 10 and includes a support 21, a handle 22, and two arms 23. The support 21 is fixed in position within the base 10. The handle 22 is translatable relative to the support 21 between a pull-out position and an initial position. Each of the opposite sides of the handle 22 is provided with an arm 23. One end of each arm 23 is rotatably connected to the support 21, and the other end is movably and rotatably connected to the handle 22. Each arm 23 is provided with an unlock pin 24.

When the handle 22 is in the initial position, the unlock pin 24 is disengaged from the card 300 plugged into the connector 30, meaning the unlock pin 24 does not interfere with the card 300. When the handle 22 translates from the initial position to the pull-out position, the handle 22 synchronously drives the two arms 23 to rotate. The unlock pin 24 moves with the arm 23 and pushes the card 300, thereby extracting the card 300 from the connector 30. This replaces the manual pulling of the card 300 by the user, providing a labor-saving effect and preventing the user from touching or pressing components on the card 300, such as a heatsink, thus avoiding damage to the card 300.

As an example, the card 300 is a PCIe (peripheral component interconnect express) card, which is a high-speed, high-bandwidth serial interconnect technology designed to connect various peripherals to a computer motherboard, such as a graphics card, sound card, network card, or hard drive.

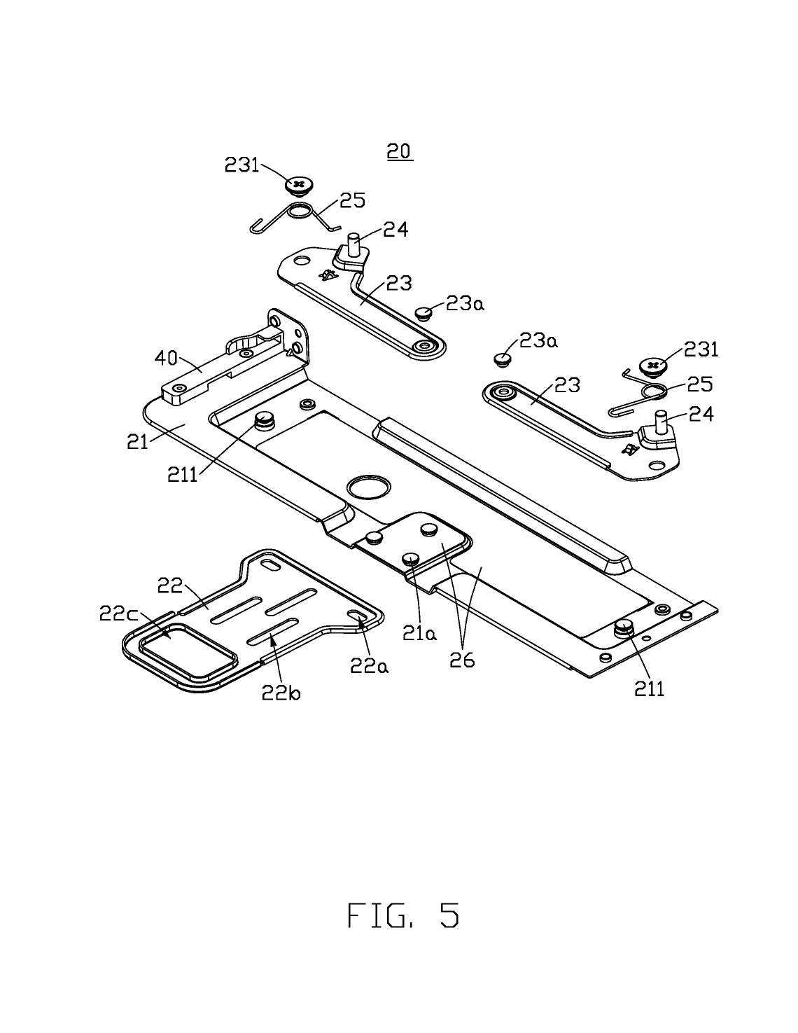

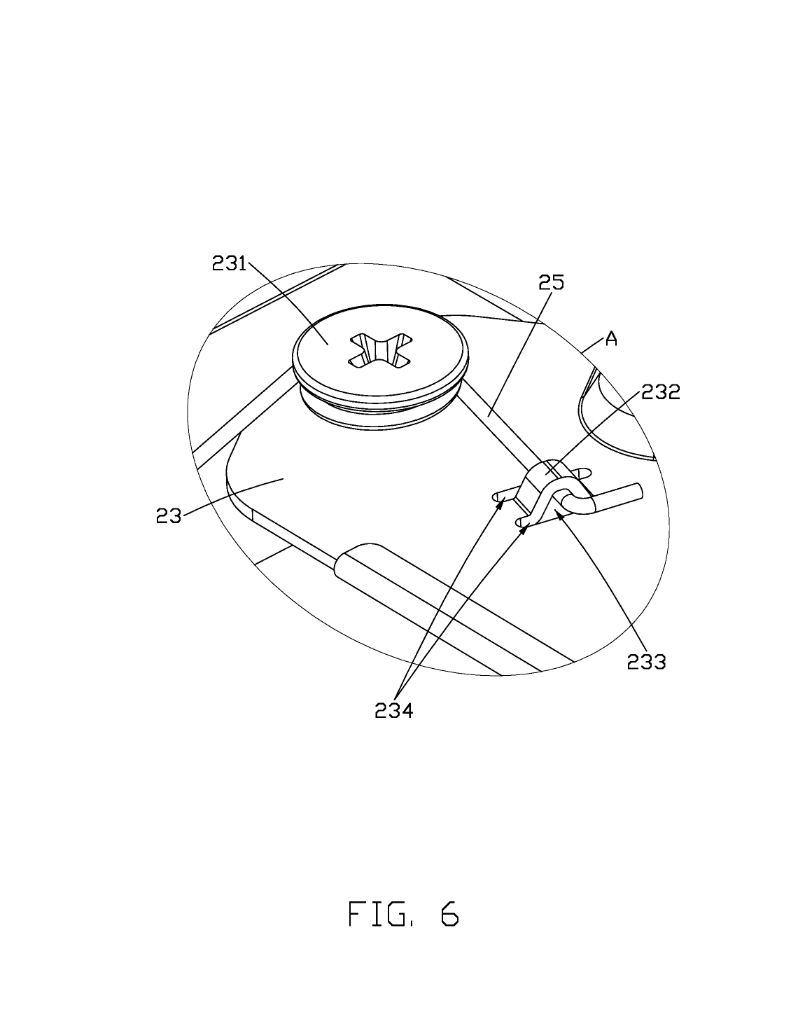

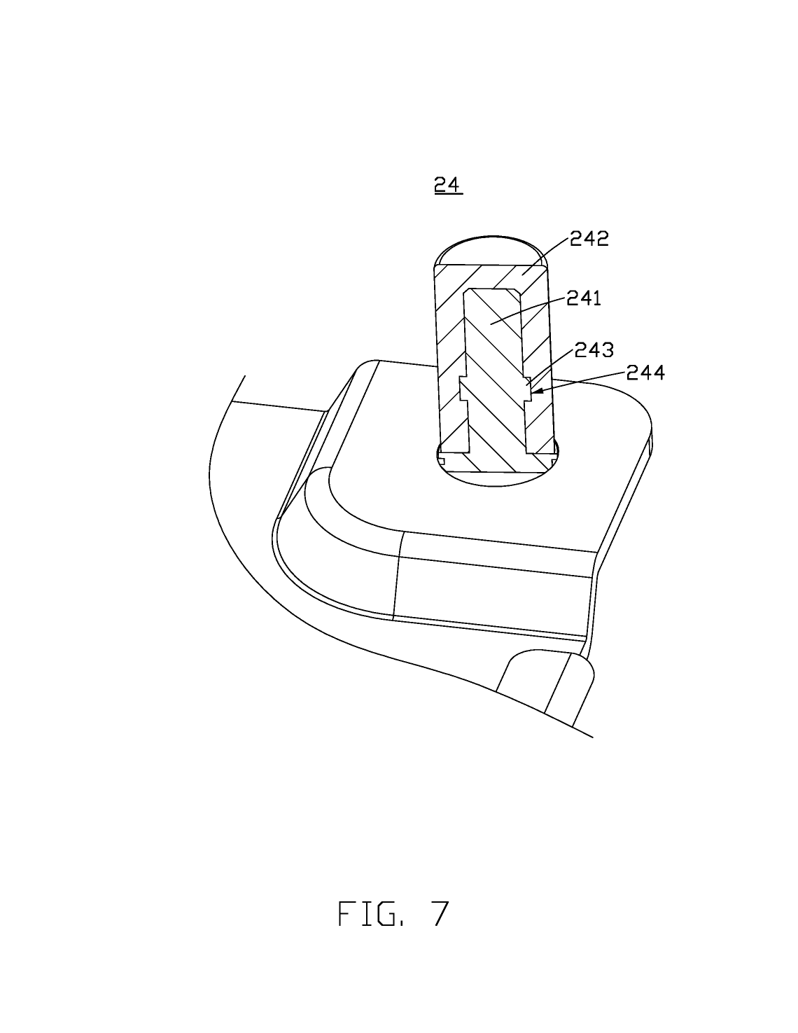

In some embodiments, as shown in FIG. 5 to FIG. 7, the support 21 is provided with two pillars 211, each corresponding to an arm 23. Each arm 23 is connected to the support 21 via a screw shaft 231. Each arm 23 is provided with a protrusion 232, and the protrusion 232 includes a hole 233. The pulling component 20 further includes two springs 25, each corresponding to an arm 23. One end of each spring 25 is wound around the pillar 211, and the other end passes through the hole 233 and is bent. The middle portion of the spring 25 is wound around the screw shaft 231. The spring 25 drives the arm 23 to reset, enabling the arm 23 to synchronously drive the handle 22 to translate from the pull-out position to the initial position. Illustratively, the pillar 211 is an T-shaped nail.

In some embodiments, the protrusion 232 is an arch-shaped sheet that arches upward. The hole 233 is formed below the arch-shaped sheet. The arm 23 has slots 234 on both sides of the arch-shaped sheet. The slots 234 provide deformation space for the arch-shaped sheet, facilitating easier deformation of the arch-shaped sheet and allowing the spring 25 to be smoothly inserted into the hole 233 during installation.

In some embodiments, the handle 22 is provided with two first slide grooves 22a, the extension direction of which is perpendicular to the translation direction of the handle 22. Each first slide groove 22a corresponds to an arm 23. Each arm 23 has a first slide pin 23a, which is inserted into the corresponding first slide groove 22a and can slide within it, connecting the handle 22 to the two arms 23. The cooperation between the first slide groove 22a and the first slide pin 23a provides sufficient degrees of freedom between the handle 22 and the arm 23, preventing jamming. For example, the first slide pin 23a is an T-shaped nail.

In some embodiments, the handle 22 is provided with multiple second slide grooves 22b, each extending along the translation direction of the handle 22. The support 21 is provided with multiple second slide pins 21a, each corresponding to a second slide groove 22b. Each second slide pin 21a is inserted into the corresponding second slide groove 22b and can slide within it to guide the translation of the handle 22, reducing wobbling and enhancing the stability of the handle 22. For example, there are three second slide pins 21a and three second slide grooves 22b, and the second slide pin 21a is an T-shaped nail.

In some embodiments, the unlock pin 24 includes an inner column 241 and an outer sleeve 242. The inner column 241 is disposed on the arm 23, and the outer sleeve 242 encases the exterior of the inner column 241. The outer sleeve 242 is made of an insulating flexible material, such as plastic. For example, the inner column 241 is made of metal to enhance the structural strength of the unlock pin 24.

In some embodiments, the inner column 241 has an annular protrusion 243 on its peripheral side, and the inner surface of the outer sleeve 242 has an annular groove 244. The annular groove 244 accommodates the annular protrusion 243 to position the inner column 241 relative to the outer sleeve 242. The annular protrusion 243 limits the movement of the outer sleeve 242.

In some embodiments, the end of the handle 22 away from the connector 30 is provided with a notch 22c. The notch 22c allows the user to grip the handle 22 manually, improving convenience.

In some embodiments, one side of the support 21 is provided with a guiding piece 40. The side of the guiding piece 40 facing the card 300 has a track groove 41. When installing the card 300, one side of the card 300 extends into the track groove 41, which guides the movement of the card 300 to facilitate its connection with the connector 30. The guiding piece 40 enhances the accuracy of the connection between the card 300 and the connector 30.

In some embodiments, a smooth sheet 26 is disposed between the support 21, the handle 22, and the arms 23. The smooth sheet 26 reduces friction between the handle 22, the arms 23, and the support 21, preventing direct friction that could cause excessive resistance. Thus, the smooth sheet 26 further contributes to the labor-saving effect.

In some embodiments, the chassis 100 further includes a cover plate 50. The cover plate 50 covers the support 21, and the handle 22 and the arms 23 are located in the gap between the cover plate 50 and the support 21. The cover plate 50 protects the handle 22 and the arms 23, preventing debris from causing jamming.

In some embodiments, when removing the card 300 from the chassis 100, the user pulls the handle 22, causing it to translate from the initial position to the pull-out position. The handle 22 drives the two arms 23 to rotate, and the unlock pin 24 moves with the arms 23 to push the card 300, extracting it from the connector 30, achieving a labor-saving effect. After the user releases the handle 22, the spring 25 drives the arms 23 to rotate, synchronously returning the handle 22 to the initial position. At this point, the unlock pin 24 does not interfere with the card 300, allowing the user to manually reinsert the card 300 into the connector 30.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A chassis comprising:
a base comprising a fixed connector configured for connecting a card; and
a pulling component comprising a support, a handle, and two arms, wherein
the support is fixed on the base, the handle is movable relative to the support between an initial position and a pull-out position, the two arms are located on either side of the handle, one end of each of the two arms is rotatably disposed on the support, another end of each of the two arms is rotatably and movably disposed on the handle, each of the two arms comprises an unlock pin;
when the handle is in the initial position, the card is pluggable into the connector; when the handle is moved to the pull-out position, the handle pulls the two arms to rotate relative to the support and push the card off the connector by the unlock pins.

2. The chassis of claim 1, wherein the support comprises two screw shafts, the end of each of the two arms rotatably disposed on the support is rotatable around a respective screw shaft of the two screw shafts, each of the two arms further comprises a protrusion with a hole, the pulling component further comprises two springs, the support further comprises two pillars, one end of each of the two springs is wound around a respective pillar of the two pillars, another end of each of the two springs is extend through the protrusion by the hole of a respective arm of the two arms and is bent to hook the protrusion, a middle section of each of the two springs is wound around a respective shaft of the two shafts, the two springs push the two arms to move the handle back to the initial position when the handle is released.

3. The chassis of claim 2, wherein the protrusion is an arch-shaped sheet, the arch-shaped sheet arches upward, the hole of the protrusion is formed below the arch-shaped sheet, each of the two arms further comprises slots on both sides of the arch-shaped sheet, a deformation space of the arch-shaped sheet is defined by the slots.

4. The chassis of claim 1, wherein the handle comprises two first slide grooves, the two first slide grooves are perpendicular to a direction of movement of the handle between the initial position and the pull-out position, each of the two arms further comprises a first slide pin, the first slide pin of each of the two arms is inserted in a respective first slide groove of the two first slide grooves, the first slide pin is slidable and rotatable in the corresponding first slide groove, so that the two arms are movable and rotatable relative to the handle.

5. The chassis of claim 1, wherein the handle comprises a plurality of second slide grooves, the plurality of second slide grooves is parallel to a direction of movement of the handle between the initial position and the pull-out position, the support comprises a plurality of second slide pins, each of the plurality of second slide pins is slidably inserted in a corresponding second slide groove of the plurality of second slide grooves, the handle is guided by the plurality of second slide pins to move between the initial position and the pull-out position.

6. The chassis of claim 1, wherein the unlock pin comprises an inner column and an outer sleeve, the inner column is set on a corresponding arm of the two arms, the outer sleeve is coated over the inner column, the outer sleeve is made of insulating flexible material, the inner column comprises an annular protrusion, an inner surface of the outer sleeve comprises an annular groove, the annular protrusion is inserted in the annular groove to position the outer sleeve on the inner column.

7. The chassis of claim 1, wherein the support comprises two smooth sheets, one of the two smooth sheets is located between the support and the handle, another one of the two smooth sheets is located between the support and the two arms, the two smooth sheets are configured for reducing frictions when the handle moves relative to the support and the two arms rotate relative to the support.

8. The chassis of claim 1, wherein the handle comprises a notch at an end away from the connector, the notch is configured for being grabbed.

9. The chassis of claim 1 further comprising a guiding piece placed beside the support, wherein the guiding piece comprises a track groove, and when installing the card, one side of the card is inserted into the track groove, the track groove guides the card to connect with the connector.

10. The chassis of claim 1 further comprising a cover plate, wherein the cover plate covers the support, the handle and the two arms are placed in a gap between the cover plate and the support, the cover plate protects the handle and the two arms.

11. A server comprising:
a connector;
a card plugged into the connector;
a base configured for supporting the connector; and
a pulling component comprising a support, a handle, and two arms, wherein
the support is fixed on the base, the handle is movable relative to the support between an initial position and a pull-out position, the two arms are located on either side of the handle, one end of each of the two arms is rotatably disposed on the support, another end of each of the two arms is rotatably and movably disposed on the handle, each of the two arms comprises an unlock pin;
when the handle is on the initial position, the card is pluggable into the connector; when the handle is pulled to the pull-out position, the handle pulls the two arms to rotate relative to the support and push the card off the connector by the unlock pins.

12. The server of claim 11, wherein the support comprises two screw shafts, the end of each of the two arms rotatably disposed on the support is rotatable around a respective screw shaft of the two screw shafts, each of the two arms further comprises a protrusion with a hole, the pulling component further comprises two springs, the support further comprises two pillars, one end of each of the two springs is wound around a respective pillar of the two pillars, another end of each of the two springs is extend through the protrusion by the hole of a respective arm of the two arms and is bent to hook the protrusion, a middle section of each of the two springs is wound around a respective shaft of the two shafts, the two springs push the two arms to move the handle back to the initial position when the handle is released.

13. The server of claim 12, wherein the protrusion is an arch-shaped sheet, the arch-shaped sheet arches upward, the hole of the protrusion is formed below the arch-shaped sheet, each of the two arms further comprises slots on both sides of the arch-shaped sheet, a deformation space of the arch-shaped sheet is defined by the slots.

14. The server of claim 11, wherein the handle comprises two first slide grooves, the two first slide grooves are perpendicular to a direction of movement of the handle between the initial position and the pull-out position, each of the two arms further comprises a first slide pin, the first slide pin of each of the two arms is inserted in a respective first slide groove of the two first slide grooves, the first slide pin is slidable and rotatable in the corresponding first slide groove, so that the two arms are movable and rotatable relative to the handle.

15. The server of claim 11, wherein the handle comprises a plurality of second slide grooves, the plurality of second slide grooves is parallel to a direction of movement of the handle between the initial position and the pull-out position, the support comprises a plurality of second slide pins, each of the plurality of second slide pins is slidably inserted in a corresponding second slide groove of the plurality of second slide grooves, the handle is guided by the plurality of second slide pins to move between the initial position and the pull-out position.

16. The server of claim 11, wherein the unlock pin comprises an inner column and an outer sleeve, the inner column is set on a corresponding arm of the two arms, the outer sleeve is coated over the inner column, the outer sleeve is made of insulating flexible material, the inner column comprises an annular protrusion, an inner surface of the outer sleeve comprises an annular groove, the annular protrusion is inserted in the annular groove to position the outer sleeve on the inner column.

17. The server of claim 11, wherein the support comprises two smooth sheets, one of the two smooth sheets is located between the support and the handle, another one of the two smooth sheets is located between the support and the two arms, the two smooth sheets are configured for reducing frictions when the handle moves relative to the support and the two arms rotate relative to the support.

18. The server of claim 11, wherein the handle comprises a notch at an end away from the connector, the notch is configured for being grabbed.

19. The server of claim 11 further comprising a guiding piece placed beside the support, wherein the guiding piece comprises a track groove, and when installing the card, one side of the card is inserted into the track groove, the track groove guides the card to connect with the connector.

20. The server of claim 11 further comprising a cover plate, wherein the cover plate covers the support, the handle and the two arms are placed in a gap between the cover plate and the support, the cover plate protects the handle and the two arms.
